(19) United States
(12) Patent Application Publication
(10) Pub. No.: US 2020/0103698 A1
(43) Pub. Date: Apr. 2, 2020

(54) COLOR FILTER AND DISPLAY PANEL

(71) Applicants: HKC Corporation Limited, Shenzhen (CN); Chongqing HKC Optoelectronics Technology Co., Ltd., Chongqing (CN)

(72) Inventor: Chuan Wu, Shenzhen (CN)

(21) Appl. No.: 16/246,532

(22) Filed: Jan. 13, 2019

Related U.S. Application Data
(63) Continuation of application No. PCT/CN2018/115864, filed on Nov. 16, 2018.

(30) Foreign Application Priority Data
Sep. 30, 2018 (CN) 201821620493.9

(51) Int. Cl. G02F 1/1335; G03F 7/00

(52) U.S. Cl. CPC G02F 1/133514; G02F 1/133512; G03F 7/0007

(57) ABSTRACT

The present application discloses a color filter and a display panel. A portion of the first photo-resistant layer, a portion of the second photo-resistant layer and a portion of the third photo-resistant layer of the color filter are laminated at a frame of the black matrix and form a photo shielding spacer. And at least a portion of the photo shielding spacer is embedded in the black matrix.

### CROSS REFERENCE TO RELATED APPLICATIONS

The present application is a Continuation Application of PCT Application No. PCT/CN2018/115864 filed on Nov. 16, 2018, which claims the benefit of Chinese Patent Application No. 201821620493.9, filed on Sep. 30, 2018, which is incorporated herein by reference in its entirety.

### TECHNICAL FIELD

The present application relates to the technical field of liquid crystal display, and in particular, to a color filter and a display panel using the color filter.

### BACKGROUND

With the development of the display technology, liquid crystal displays such as flat panel display are widely used in various consumer electronic products such as mobile phones, televisions, personal digital assistants, digital cameras, and notebook computers and desktop computers and the like, due to its high image quality, power efficiency, thin body, and zero radiation and the like, which has become the mainstream in display devices.

A majority of the liquid crystal displays is backlight liquid crystal displays, including housing, liquid crystal display panel defined in the housing and a backlight module defined in the housing.

A traditional liquid crystal display panel is laminated by a piece of thin film transistor array substrate and a piece of color filter substrate. A pixel electrode and a common electrode are respectively formed at the array substrate and the color filter and liquid crystal is filled between the array substrate and the color filter. The working principle lies in an electric field formed between the pixel electrode and the common electrode to control the deflection of the liquid crystal molecules in the liquid crystal layer, by means of a driving voltage applied between the pixel electrode and the common electrode. An image is produced by the refracted light of the backlight module.

The color filter substrate is an indispensable component in the liquid crystal display panel. The preparation processes of the color filter substrate include the steps of: from black matrix to red/green/blue resistance unit, and to common electrode, and to column spacer. Since the red, green, and blue resistance units are respectively prepared by an individual process, and the black matrix, the common electrode, and the column spacers are respectively prepared by an individual process, so the preparation process of the color filter substrate usually demands six processes in total. If the primary spacer is prepared separately from the secondary spacer during preparation of the column spacer, then one more process has to be added, demanding seven processes in total. The production cost of the substrate is rather high, because of the numerous processes.

### SUMMARY

The present application aims to provide a color filter, simplifying the preparation processes of the color filter. The production cost is reduced and production efficiency is improved.

To fulfill such intention, the present application provides a color filter, including:

a substrate;

a black matrix, defined on a surface of the substrate; a plurality of sub pixel regions are formed and enclosed with an interval by the black matrix; the sub pixel regions includes a first sub pixel region, a second sub pixel region and a third sub pixel region; and

a color filtering layer, the color filtering layer includes a first photo-resistant layer, a second photo-resistant layer and a third photo-resistant layer; a portion of the first photo-resistant layer, a portion of the second photo-resistant layer and a portion of the third photo-resistant layer are respectively placed at the first sub pixel region, the second sub pixel region and the third sub pixel region;

another portion of the first photo-resistant layer, another portion of the second photo-resistant layer and another portion of the third photo-resistant layer are laminated at a frame of the black matrix and forms a photo shielding spacer; and at least a portion of the photo shielding spacer is embedded in the black matrix.

Optionally, the first photo-resistant layer is a red photo-resistant layer, and the second photo-resistant layer is a green photo-resistant layer, and the third photo-resistant layer is a blue photo-resistant layer.

Optionally, the photo shielding spacer is laminated by the first photo-resistant layer, the second photo-resistant layer and the third photo-resistant layer in sequence.

Optionally, a gap is provided on the black matrix for communicating two adjacent sub pixel regions of the sub pixel regions; the gap extends to the substrate in a thickness direction of the black matrix; the photo shielding spacer is embedded in the gap.

Optionally, a groove is concavely defined in the black matrix; the photo shielding spacer is embedded in the gap.

Optionally, an auxiliary electrode is further covered on the photo shielding spacer.

Optionally, an orthographic projection of the photo shielding spacer on the substrate is; located in a region of an orthographic projection of the black matrix on the substrate.

Optionally, a section shape of the photo shielding spacer is trapezoid or rectangular.

In some exemplary embodiments of the present application, the color filter includes:

a substrate;

a black matrix, defined on a surface of the substrate; a plurality of sub pixel regions are formed and enclosed with an interval by the black matrix; the sub pixel regions includes a first sub pixel region, a second sub pixel region and a third sub pixel region; and

a color filtering layer, the color filtering layer comprises a red photo-resistant layer, a green photo-resistant layer and a blue photo-resistant layer; wherein a portion of the red photo-resistant layer, a portion of the green photo-resistant layer and a portion of the blue photo-resistant layer are respectively located in the first sub pixel region, the second sub pixel region and the third sub pixel region;

another portion of the red photo-resistant layer, another portion of the green photo-resistant layer and another portion of the blue photo-resistant layer are laminated at a frame of the black matrix and forms a photo shielding spacer; and at least a portion of the photo shielding spacer is embedded in the black matrix; an electrode layer is covered on the photo shielding spacer.

The present application further provides a display panel. The display panel includes:

a substrate;

a black matrix, defined on a surface of the substrate; a plurality of sub pixel regions are formed and enclosed with an interval by the black matrix; the sub pixel regions includes a first sub pixel region, a second sub pixel region and a third sub pixel region; and

a color filtering layer, the color filtering layer includes a first photo-resistant layer, a second photo-resistant layer and a third photo-resistant layer; a portion of the first photo-resistant layer, a portion of the second photo-resistant layer and a portion of the third photo-resistant layer are respectively located at the first sub pixel region, the second sub pixel region and the third sub pixel region;

another portion of the first photo-resistant layer, another portion of the second photo-resistant layer and another portion of the third photo-resistant layer are laminated at a frame of the black matrix and forms a photo shielding spacer; and at least a portion of the photo shielding spacer is embedded in the black matrix.

In some exemplary embodiments of the present application, the display panel includes:

a substrate;

a black matrix, defined on a surface of the substrate; a plurality of sub pixel regions are formed and enclosed with an interval by the black matrix; the sub pixel regions includes a first sub pixel region, a second sub pixel region and a third sub pixel region; and

a color filtering layer, the color filtering layer includes a red photo-resistant layer, a green photo-resistant layer and a blue photo-resistant layer; a portion of the red photo-resistant layer, a portion of the green photo-resistant layer and a portion of the blue photo-resistant layer are respectively located in the first sub pixel region, the second sub pixel region and the third sub pixel region;

another portion of the red photo-resistant layer, another portion of the green photo-resistant layer and another portion of the blue photo-resistant layer are laminated at a frame of the black matrix and forms a photo shielding spacer; and at least a portion of the photo shielding spacer is embedded in the black matrix; an electrode layer is covered on the photo shielding spacer.

The solution of the present application, by means of laminating of a plurality of photo resist layer in the process of producing color filtering layer, allows the spacer and the color filter to be produced in one process, thereby saving a process of preparing the spacer individually and saving the preparation of photo-resistant material and the mask of the spacer. Production cost is thus reduced with improved production efficiency and capability. Further, in the preparation process of the photo shielding spacer of the present application, at least portion of the photo shielding spacer is embedded into the black matrix. So on the basis of thick photo-resistant layer material, the spacing of the display panel of the color filter can be effectively controlled in the present application, securing the performance of the display panel.

### BRIEF DESCRIPTION OF THE DRAWINGS

In order to illustrate the exemplary embodiments of the present application or the technical solutions in the prior art more clearly, the drawings involved in the exemplary embodiments or the prior art will be briefly described in the following. Obviously, the drawings below are only description of some exemplary embodiments of the present application, and other drawings can be conceived by those skilled in the art according to the structures shown in the drawings without any creative effort.

FIG. 1 is a top structural schematic diagram of the first exemplary embodiment of the display panel of the present application;

FIG. 2 is a cross-section diagram along the A1-A1 line shown in FIG. 1;

FIG. 3 is a cross-section diagram along the A2-A2 line shown in FIG. 1;

FIG. 4 is a top structural schematic diagram of the second exemplary embodiment of the display panel of the present application;

FIG. 5 is a cross-section diagram along the A3-A3 line shown in FIG. 4;

FIG. 6 is a cross-section diagram along the A4-A4 line shown in FIG. 4;

FIG. 7 is a top structural schematic diagram of the third exemplary embodiment of the display panel of the present application;

FIG. 8 is a cross-section diagram along the A5-A5 line shown in FIG. 7;

FIG. 9 is a cross-section diagram along the A6-A6 line shown in FIG. 7;

FIG. 10 is a cross-section structural schematic diagram of the fourth exemplary embodiment of the display panel of the present application.

### DESCRIPTION OF THE REFERENCE NUMERALS

| Reference | | Reference | |
|---|---|---|---|
| numeral | Name | numeral | Name |
| 300 | Display panel | 123 | Third sub pixel region |
| 200 | Array substrate | 124 | Gap |
| 210 | Glass substrate | 124a | Groove |
| 220 | Conductive film | 125 | Photo shielding layer |
| 100 | Color filter | 130 | Color filtering layer |
| 110 | Substrate | 131 | First photo-resistant |
| | | | layer |
| 120 | Black matrix | 132 | Second |
| | | | photo-resistant layer |
| 121 | First sub pixel region | 133 | Third photo-resistant |
| | | | layer |
| 122 | Second sub pixel | | |
| | region | | |

The implementation, functional features and advantages of the present application will be further described referring to the drawings.

### DETAILED DESCRIPTION OF THE EMBODIMENTS

The technical solution in the exemplary embodiment of the present application will be described clearly and completely in the following with reference to the drawings. Obviously, the described exemplary embodiment is only a portion of the exemplary embodiments of the present application, but not all. Based on the exemplary embodiments of the present application, all other exemplary embodiments conceived those skilled in the art without creative effort shall be included within the protection scope of the present application.

It should be noted that all directional indications (such as up, down, left, right, front, back, etc.) in the exemplary embodiments of the present application are only used to explain the relative positional relationship and movement between the components in a certain posture (as shown in the drawings), and if the specific posture changes, the directional indications will change accordingly.

In the present application, unless otherwise expressly specified and defined, the terms “connected”, “fixed” and the like shall be broadly understood. For example, “fixed” may be a fixed connection, a detachable connection, or an integral body. It also can be a mechanical connection or an electrical connection. It can be directly connected or indirectly connected through an intermediate medium. It can be the internal communication of two elements or the interaction relationship between two elements, unless otherwise clearly defined. For those skilled in the art, the specific meaning of the above terms in the present application should be understood according to the specific circumstances.

In addition, in the present application, the wording such as “first” and “second” are used for descriptive purposes only, and should not be understood as indicating or implying its relative importance or implicitly indicating the number of indicated technical features. Thus, features defining “first” and “second” may explicitly or implicitly include at least one such feature. In addition, the technical solutions between the various exemplary embodiments may be combined with each other, but must be based on what those skilled in the art can achieve. When the combination of technical solutions is contradictory or impossible to achieve, it should be considered that the combination of such technical solutions does not exist and should not be included within the protection scope required of the present application.

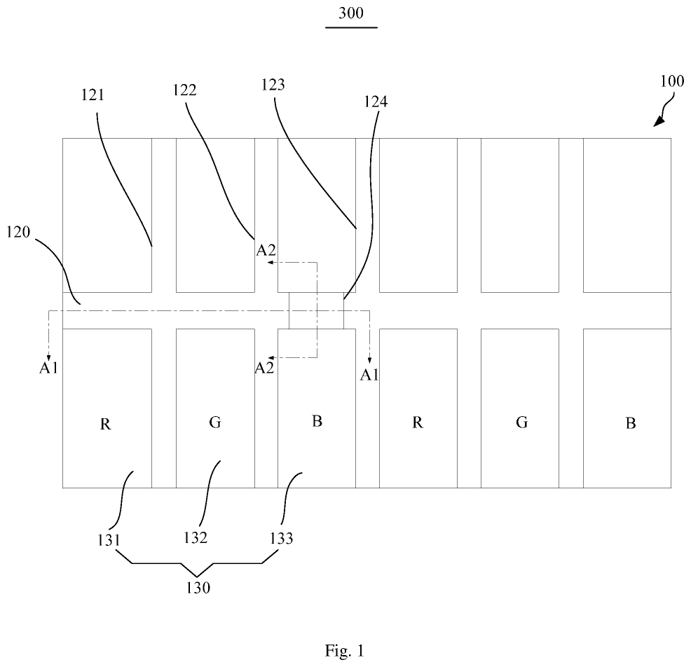

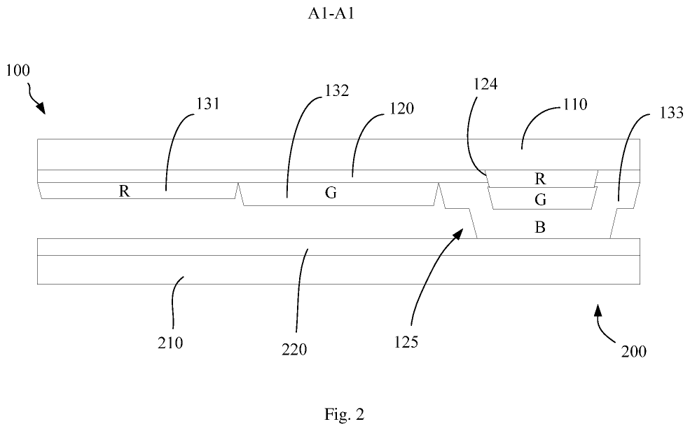

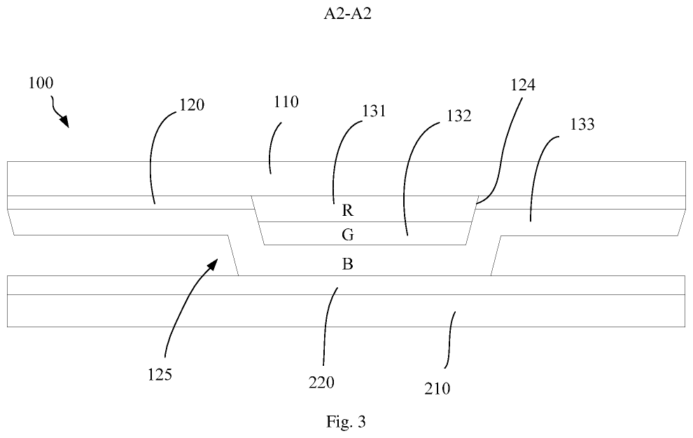

The present application provides a color filter 100. Referring to FIGS. 1 to 3, the color filter 100 and the array substrate 200 are arranged opposite to each other in the liquid crystal panel of the liquid crystal display. The array substrate 200 includes a glass substrate 210 and a conductive film 220 covering the glass substrate 210. The photo shielding spacer 125 is located between the color filter 100 and the array substrate 200, to support the color filter 100 and the array substrate 200 and to ensure a proper spacing between the color filter 100 and the array substrate 200. The photo shielding spacer 125 can play a role in homogenizing the flowing liquid crystal layer between the color filter 100 and the array substrate 200, and can ensure the filling amount of liquid crystal, preventing the adverse effect of liquid crystal dropping error on the product.

The color filter 100 of the present application, includes the substrate 100, the black matrix 120 defined on a surface of the substrate 100. A plurality of sub pixel regions are formed and enclosed with an interval by the black matrix 120. The sub pixel regions comprise a first sub pixel region 121, a second sub pixel region 122 and a third sub pixel region 123. The color filtering layer 130 includes a first photo-resistant layer 131, a second photo-resistant layer 132 and a third photo-resistant layer 133. A portion of the first photo-resistant layer 131, a portion of the second photo-resistant layer 132 and a portion of the third photo-resistant layer 133 are respectively placed at the first sub pixel region 121, the second sub pixel region 122 and the third sub pixel region 123. Another portion of the first photo-resistant layer 131, another portion of the second photo-resistant layer 132 and another portion of the third photo-resistant layer 133 are laminated at a frame of the black matrix 120 and form a photo shielding spacer 125. At least a portion of the photo shielding spacer 125 is embedded in the black matrix 120.

The substrate 100 could be plastic, resin, glass and the like. In the manufacturing process of the color filter 100, the substrate 100 is first cleaned, then a black photo-resistant material is provided, and the substrate 100 is coated with a black photo-resistant material, which can be Cr or acrylic resin doped with black pigment (mainly carbon). For example, carbon, Ti, Ni and other raw materials are mixed into the photo-resistant to form a black resin. The black matrix 120 is prepared by exposing and developing a black photo-resistant material using a mask. In the present application, the first photo-resistant layer 131 is a red photo-resistant layer, the second photo-resistant layer 132 is a green photo-resistant layer, and the third photo-resistant layer 133 is a blue photo-resistant layer. The first photo-resistant layer 131, the second photo-resistant layer 132, and the third photo-resistant layer 133 are respectively exposed and developed by halftone illumination, so as to sequentially produce a red photo-resistant layer located in the first sub-pixel region 121, a green photo-resistant layer located in the second sub-pixel region 122, and a blue photo-resistant layer located in the third sub-pixel region 123. In the process of preparing the color filtering layer 130, a portion of the red photo-resistant layer, a portion of the green photo-resistant layer, and a portion of the blue photo-resistant layer are laminated on the black matrix 120 to form a photo shielding spacer 125. In the present application the photo shielding spacer 125 is formed while preparing the color filtering layer 130. It can be understood that the red photo-resistant layer, the green photo-resistant layer, and the blue photo-resistant layer have light-tight properties after being laminated based on the principle of three primary colors, so that light can be effectively shielded at the black matrix 120. In other exemplary embodiments, the photo shielding spacer 125 may be formed by sandwiching a photo shielding layer made of photo shielding material between two adjacent photo-resistant layers, on the basis of laminating the three photo-resistant layers.

According to the technical solution of the present application, the photo shielding spacer 125 is manufactured by laminating a plurality of photo-resistant layers in the process of manufacturing the color filtering layer 130, so that the spacer and the color filtering layer 130 can be formed in the same process, thereby saving a process for manufacturing the spacer individually, saving the photo-resistant material and the mask for manufacturing the spacer, thereby reducing the production cost and improving the production efficiency and production capacity. Further, in the process of manufacturing the photo shielding spacer 125, the photo shielding spacer 125 is at least partially embedded in the black matrix 120, so that the spacing (cell gap) of the display panel 300 having the color filter 100 of the present application can be effectively controlled on the basis of a thick photo-resistant material, so that the quality of the display panel 300 can be guaranteed.

In the present application, embedding the photo shielding spacer 125 in the black matrix 120 can effectively adjust the height of the photo shielding spacer 125 and ensure the spacing between the color filter 100 and the array substrate 200 in the display panel 300. Specifically, refer to FIGS. 1 to 3 again. In some exemplary embodiments, the black matrix 120 is provided with a gap 124 connecting two adjacent sub-pixel regions, the gap 124 extends to the substrate 100 in the thickness direction of the black matrix 120, and the photo shielding spacer 125 is embedded in the gap 124. The gap 124 can be formed in the process of manufacturing the black matrix 120. Since the photo shielding spacer 125 of the present application is formed by laminating three photo-resistant layers of red, green and blue, and is opaque. The photo shielding spacer 125 can perform photo shading for the black matrix 120 when the gap 124 extends to the substrate 100, thus not affecting the quality of the entire display panel 300. The cell gap of the display panel 300 can be effectively controlled by the gap 124, facilitating the fabrication of the entire color filter 100.

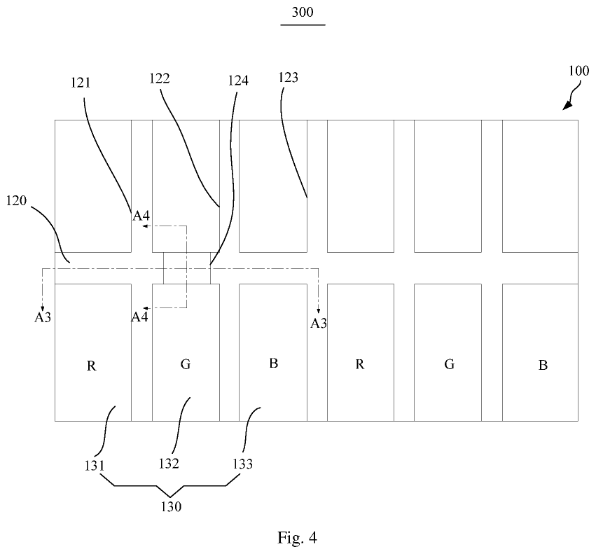

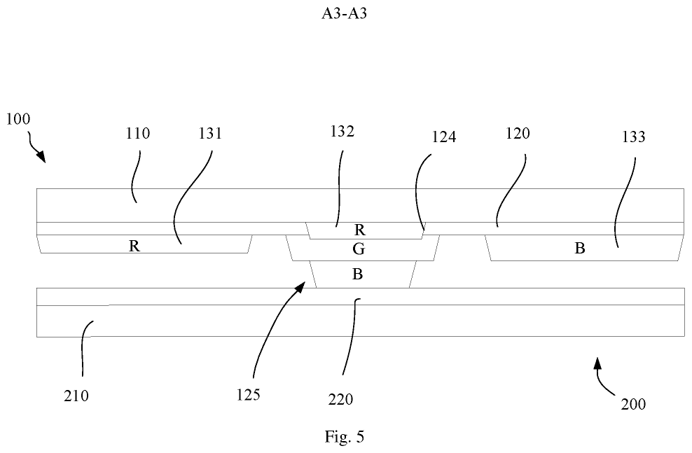

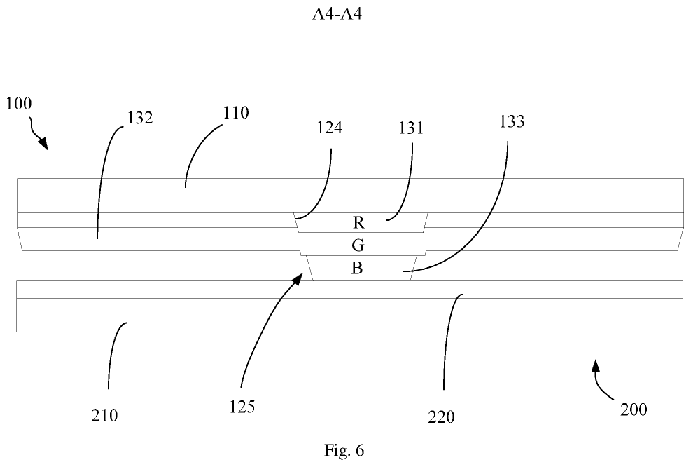

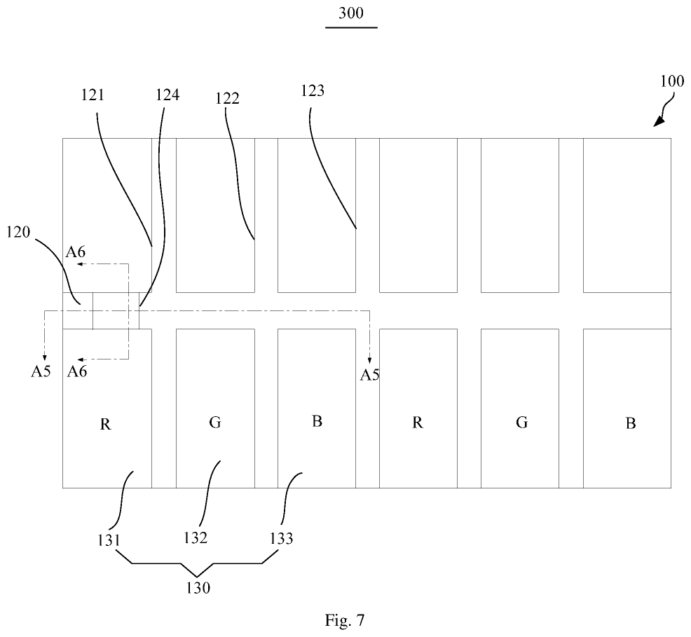

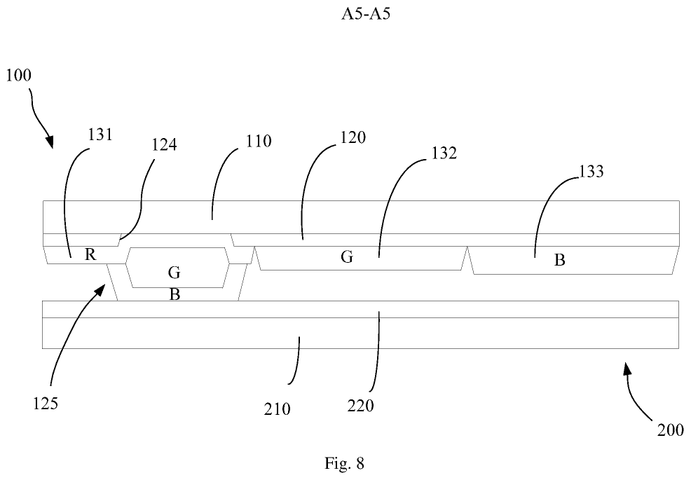

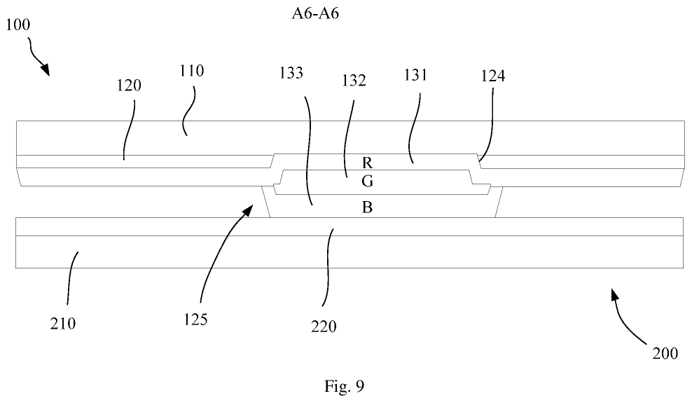

Further, given that the shading spacer 125 is embedded by providing the gap 124 in the black matrix 120, a plurality of shading spacer 125 may be provided. The shading spacer 125 may be evenly distributed on the black matrix 120 and may be provided at the border of the black matrix 120 corresponding to one of the red photo-resistant layer, the green photo-resistant layer, or the blue photo-resistant layer. As shown in FIGS. 1 to 3, i.e., the shading spacer 125 is laminated at the border of the black matrix 120 at the blue photo-resistant layer (BLUE, corresponding to B in the drawing). As shown in FIGS. 4 to 6, the photo shielding spacer 125 is laminated at the position of the green photo-resistant layer (GREEN, corresponding to G in the drawings), and as shown in FIGS. 7 to 9, the photo shielding spacer 125 is laminated at the position of the red photo-resistant layer (RED, corresponding to R in the drawings). The specific process could be: forming a gap 124 in the photolithography and developing process of making the black matrix 120, followed by laminating in sequence of a portion of the red photo-resistant layer, a portion of the green photo-resistant layer, and a portion of the blue photo-resistant layer, to form the photo shielding layer 125. When the photo shielding spacer 125 is laminated at the border of the black matrix 120 at the blue photo-resistant layer, the blue photo-resistant layer at the gap 124 is connected to the blue photo-resistant layers of two adjacent third sub-pixel regions 123, while the red photo-resistant layer and the green photo-resistant layer in the gap 124 exist separately in the region of the gap 124. When the photo shielding spacer 125 is laminated at other photo-resistant layers, the laminating structure will be referred to the blue photo-resistant layer and will not be described herein in details.

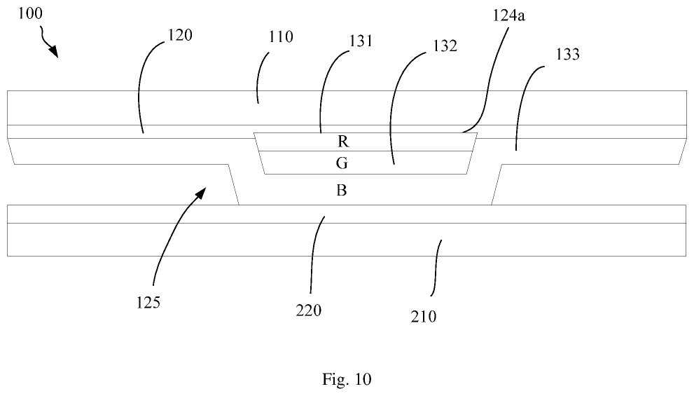

Referring to FIG. 1-10, in some other exemplary embodiments of the present application, the black matrix 120 may also be concavely formed with a groove (not shown in the drawings) and the photo shielding spacer 125 is embedded in the groove. In the present exemplary embodiment, a portion of the black matrix 120 is separated as a bottom wall of the groove between the groove and the substrate 100. The groove could be formed by changing light intensity in the process of lithography in the thickness direction in the process of manufacturing the black matrix 120 to retain portion of the black matrix 120. By providing the groove, it is beneficial to increase the height of the photo shielding spacer 125 and meet the cell gap requirement of the display panel 300.

Further, the forward projection of the photo shielding spacer 125 on the substrate 100 is within the forward projection range of the black matrix 120 on the substrate 100. With this arrangement, it is possible to prevent the photo shielding spacer 125 from affecting the aperture ratio of the pixel.

The cross-sectional shape of the photo shielding spacer 125 of the present application is trapezoidal or rectangular. According to the present application, the cross-sectional shape of the photo shielding spacer 125 can be trapezoidal, so that the photo shielding spacer 125 can be support the color filter 100 and the array substrate 200 more stably.

The photo shielding spacer 125, formed by laminating in sequence the red photo-resistant layer, the green photo-resistant layer, and the blue photo-resistant layer, is simultaneously formed in the process of manufacturing the color filtering layer 130. The electrode layer is then formed on the color filtering layer 130, and the photo shielding spacer 125 is also covered with the electrode layer.

Please refer to FIGS. 1 to 10 again. The present application also proposes a display panel 300, which includes a color filter 100 and a matrix substrate 100 arranged on a cell. The specific structure of the color filter 100 refers to the above-mentioned exemplary embodiment. Since the display panel 300 adopts all the technical solutions of all the above-mentioned exemplary embodiments, it has at least all the beneficial effects brought by the technical solutions of the above-mentioned exemplary embodiments and will not be described in detail herein.

The above is only optional exemplary embodiment of the present application and is not intended to limit the scope of the present application. Any equivalent structural change made by using the contents of the specification and drawings of the present application or directly/indirectly applied in other related technical fields is included in the scope of the present application under the inventive concept of the present application.

What is claimed is:

1. A color filter, wherein, the color filter comprises:
a substrate;
a black matrix, defined on a surface of the substrate, a plurality of sub pixel regions being formed and enclosed with an interval by the black matrix, the sub pixel regions comprising a first sub pixel region, a second sub pixel region, and a third sub pixel region; and
a color filtering layer, comprising a first photo-resistant layer, a second photo-resistant layer, and a third photo-resistant layer; a portion of the first photo-resistant layer, a portion of the second photo-resistant layer, and a portion of the third photo-resistant layer being respectively located at the first sub pixel region, the second sub pixel region, and the third sub pixel region;
another portion of the first photo-resistant layer, another portion of the second photo-resistant layer, and another portion of the third photo-resistant layer being laminated at a frame of the black matrix and forming a photo shielding spacer; and at least a portion of the photo shielding spacer being embedded in the black matrix.

2. The color filter of claim 1, wherein, the first photo-resistant layer is a red photo-resistant layer, and the second photo-resistant layer is a green photo-resistant layer, and the third photo-resistant layer is a blue photo-resistant layer.

3. The color filter of claim 2, wherein, the photo shielding spacer is laminated by the first photo-resistant layer, the second photo-resistant layer and the third photo-resistant layer in sequence.

4. The color filter of claim 3, wherein, a gap is provided on the black matrix for communicating two adjacent sub pixel regions of the sub pixel regions, the gap extends to the substrate in a thickness direction of the black matrix, the photo shielding spacer is embedded in the gap.

5. The color filter of claim 3, wherein, a groove is concavely defined in the black matrix, the photo shielding spacer is embedded in the gap.

6. The color filter of claim 5, wherein, an orthographic projection of the photo shielding spacer on the substrate is located in a region of an orthographic projection of the black matrix on the substrate.

7. The color filter of claim 1, wherein, a plurality of photo shielding spacers are defined; the photo shielding spacers are evenly arranged with an interval on the black matrix.

8. The color filter of claim 1, wherein, an orthographic projection of the photo shielding spacer on the substrate is located in a region of an orthographic projection of the black matrix on the substrate.

9. The color filter of claim 8, wherein, a section shape of the photo shielding spacer is trapezoid.

10. The color filter of claim 8, wherein, a section shape of the photo shielding spacer is rectangular.

11. A color filter, wherein the color filter comprises:
a substrate;
a black matrix, defined on a surface of the substrate, a plurality of sub pixel regions being formed and enclosed with an interval by the black matrix; the sub pixel regions comprising a first sub pixel region, a second sub pixel region and a third sub pixel region; and
a color filtering layer, comprising a red photo-resistant layer, a green photo-resistant layer, and a blue photo-resistant layer, a portion of the red photo-resistant layer, a portion of the green photo-resistant layer, and a portion of the blue photo-resistant layer being respectively located in the first sub pixel region, the second sub pixel region, and the third sub pixel region;
another portion of the red photo-resistant layer, another portion of the green photo-resistant layer, and another portion of the blue photo-resistant layer being laminated at a frame of the black matrix and forming a photo shielding spacer; and at least a portion of the photo shielding spacer being embedded in the black matrix; an electrode layer being covered on the photo shielding spacer.

12. A display panel, wherein, the display panel comprises a color filter, the color filter comprises:
a substrate;
a black matrix, defined on a surface of the substrate, a plurality of sub pixel regions being formed and enclosed with an interval by the black matrix, the sub pixel regions comprising a first sub pixel region, a second sub pixel region, and a third sub pixel region; and
a color filtering layer, comprising a first photo-resistant layer, a second photo-resistant layer, and a third photo-resistant layer; a portion of the first photo-resistant layer, a portion of the second photo-resistant layer, and a portion of the third photo-resistant layer being respectively located at the first sub pixel region, the second sub pixel region, and the third sub pixel region;
another portion of the first photo-resistant layer, another portion of the second photo-resistant layer, and another portion of the third photo-resistant layer being laminated at a frame of the black matrix and forming a photo shielding spacer; and at least a portion of the photo shielding spacer being embedded in the black matrix.

13. The display panel of claim 12, wherein, the first photo-resistant layer is a red photo-resistant layer, and the second photo-resistant layer is a green photo-resistant layer, and the third photo-resistant layer is a blue photo-resistant layer.

14. The display panel of claim 13, wherein, the photo shielding spacer is laminated by the first photo-resistant layer, the second photo-resistant layer and the third photo-resistant layer in sequence.

15. The display panel of claim 14, wherein, a gap is provided on the black matrix for communicating two adjacent sub pixel regions of the sub pixel regions, the gap extends to the substrate in a thickness direction of the black matrix, the photo shielding spacer is embedded in the gap.

16. The display panel of claim 14, wherein, a groove is concavely defined in the black matrix, the photo shielding spacer is embedded in the gap.

17. The display panel of claim 12, wherein, an orthographic projection of the photo shielding spacer on the substrate is located in a region of an orthographic projection of the black matrix on the substrate.

18. The display panel of claim 12, wherein, an electrode layer being covered on the photo shielding spacer.
